(19) United States
(12) Patent Application Publication
(10) Pub. No.: US 2026/0215235 A1
(43) Pub. Date: Jul. 23, 2026

(54) PROCESSES FOR PLANARIZATION OF A SEMICONDUCTING WAFER SUBSTRATE

(71) Applicant: Taiwan Semiconductor Manufacturing Company, LTD., Hsinchu (TW)

(72) Inventors: Hsuan-Chin Lu, Hsinchu (TW); Yu-Luen Deng, Tainan (TW); Chih-Kai Yang, Taipei (TW); Min-Feng Shieh, Yongkang (TW)

(21) Appl. No.: 19/027,037

(22) Filed: Jan. 17, 2025

(51) Int. Cl. H01L 21/3105; H01L 21/66

(52) U.S. Cl. CPC H10P 95/06; H10P 74/203

(57) ABSTRACT

Methods, systems, and tools for planarizing a layer of a semiconducting wafer substrate are disclosed. The topography of a field on the layer is measured, wherein the field has a surface area that is much smaller than the surface area of the substrate. A deposition pattern for obtaining a flat or planar surface is then determined. A curable material is deposited upon the field using the deposition pattern. The curable material is then imprinted with a field-sized superstrate to create a flat or planar surface. The curable material is then cured, for example by using a radiation source. The field-sized superstrate is then lifted off the cured material to obtain the planarized layer.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device. Desirably, each layer has a flat surface.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an illustrative plan view of a shot map overlaid upon a wafer substrate.

FIG. 1B is a perspective illustration of a first field-sized superstrate over the shot map and the wafer substrate, in accordance with some embodiments. The first field-sized superstrate has an area corresponding to one shot of the shot map.

FIG. 1C is a perspective illustration of a second field-sized superstrate over the shot map and the wafer substrate, in accordance with some embodiments. The second field-sized superstrate has an area corresponding to six shots of the shot map.

FIG. 2A is a schematic side cross-sectional view of a planarization tool for performing inkjet adaptive planarization (IAP), in accordance with some embodiments.

FIG. 2B is a plan view showing some additional aspects of the planarization tool.

FIG. 3 is a flow chart illustrating a method for planarizing a top layer of a substrate, in accordance with some embodiments.

FIG. 4 is a cross-sectional view showing a wafer substrate with a material layer thereon and curable material being deposited within a field.

FIG. 5 is a cross-sectional view showing the wafer substrate after a field-sized superstrate has been applied to the curable material.

FIG. 6 is a magnified cross-sectional view showing the extrusion of some curable material along the edges of the field-sized superstrate.

FIG. 7 is a cross-sectional view illustrating the emission of radiation for curing the curable material within the field to obtain a planarized top layer.

FIG. 8 is a cross-sectional view illustrating the substrate after planarization in multiple fields. Recesses between fields are visible.

FIG. 9 is a cross-sectional view illustrating another embodiment. Here, the curable material has been deposited such that a portion of the non-flat material layer forms a portion of the planarized surface.

FIG. 10 is a cross-sectional view of a transistor formed upon a substrate and a redistribution layer thereon, for illustrating various layers that can be planarized.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to systems and devices which are made up of multiple components and/or different layers. When the terms “on” or “upon” or “over” are used with reference to two different components or layers, they indicate merely that one component/layer is on or upon or over the other component/layer. These terms do not require the two components/layers to directly contact each other, and permit other components/layers to be between them. The term “directly” may be used to indicate two components/layers directly contact each other without any other components/layers in between them. In addition, when referring to performing process steps to a component/substrate, this should be construed as performing such steps to whatever layers may be present on the component/substrate as well, depending on the context.

The present disclosure relates to methods for planarization of the top layer on a semiconducting wafer substrate. In this regard, planarization is performed to provide a flat surface, or in other words a surface with high uniform thickness or with low surface roughness. As layers of different materials are added upon the substrate, the topography or the variation in height upon the substrate may change undesirably. Flat surfaces are desirable for forming additional layers upon the substrate. Flat surfaces also improve process uniformity and predictability, as well as parameters like critical dimension (CD).

The present disclosure provides methods and systems/tools for planarizing the top layer of a substrate, which use inkjet adaptive planarization (IAP) techniques. In IAP, a curable material is deposited upon the top layer of the wafer substrate. The curable material is deposited based on the topography of the top layer, and fills in the valleys thereon. A superstrate is then pressed against the curable material, and the curable material is cured or polymerized to create a flat surface. The superstrate is then removed. In the present disclosure, a field-sized superstrate is used rather than a superstrate that covers the entire wafer substrate.

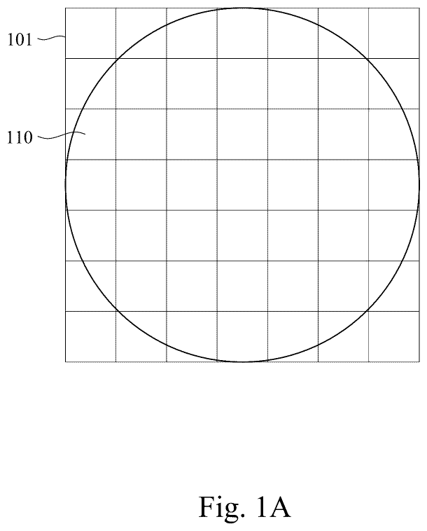

FIG. 1A is an illustrative plan view of a shot map 101 overlaid upon a wafer substrate 110. In photolithographic patterning, a reticle or photomask includes a desired mask pattern that corresponds to a given layer to be formed on the substrate. The mask pattern may include, for example, the pattern for one or more chip areas/dies and/or one or more scribe lines between chip area(s). Light is reflected off the surface of the reticle (for a reflective mask) or transmitted through the reticle (for a transmission mask) to transfer the pattern to a photoresist on the wafer substrate. This light exposure is also referred to as a shot, and the shot map shows where the exposures will be made across the surface of the wafer substrate. In this illustrative diagram, the shot map is an 8×8 grid of shots. This is only illustrative, and the present disclosure contemplates that the shot map may have any appropriate number of shots along either the X-axis or the Y-axis, and that the shots may be rectangular as desired.

FIG. 1B is a perspective illustration of a field-sized superstrate 200 over the shot map 101 and the wafer substrate 110, in accordance with some embodiments. The shot map 101 and the substrate 110 correspond to that illustrated in FIG. 1A. In this embodiment, the field-sized superstrate 200 has a surface area corresponding to one shot of the shot map. In the embodiment of FIG. 1C, the field-sized superstrate 200 has a surface area corresponding to six shots of the shot map.

It should be noted that the shot map 101 here is illustrated as having no overlapping areas between shots. However, overlapping areas may occur in the shot map. Similarly, scribe lines between the chip/die areas may be overlapped or gapped between shots as well. Generally, the field-sized superstrate is much smaller than the wafer substrate. For example, in some embodiments the field-sized superstrate has a surface area that is at most ⅓, or at most ¼, or at most ⅕, or at most 1/10 of the surface area of the substrate upon which it is used. The surface area of the substrate may vary depending on the diameter of the substrate, which can range for example from 150 mm to 300 mm or to 450 mm. In some other embodiments, the size of the field-sized superstrate corresponds to the exposure field size. For example, the TWINSCAN NXE:3400B EUV lithography system made by ASML has a maximum scanned exposure field size of 26 mm×33 mm, and the superstrate may have such dimensions. In other embodiments, the field-sized superstrate 200 may have a surface area of about 800 mm² to about 6000 mm², including from about 800 mm² to about 900 mm², or from about 1600 mm² to about 2000 mm², or ranges having any combination of these endpoints. Other endpoints and ranges are also within the scope of this disclosure. By way of comparison, a 300-mm diameter wafer substrate has a surface area of about 70,650 mm². Then, for a field size of 26 mm×33 mm, the wafer substrate may accommodate around 60 full fields and around 25 partial fields. The number of dies/chips that could be produced on the 300-mm wafer would depend on the design of the field.

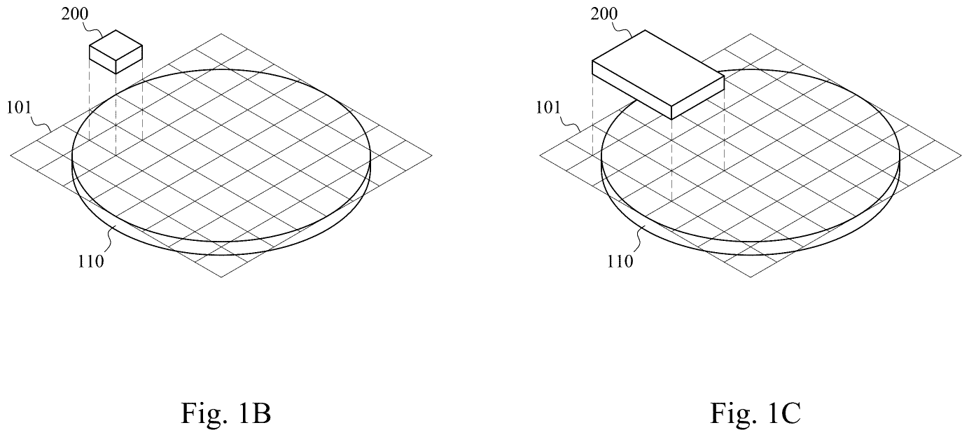

FIG. 2A is a schematic side cross-sectional view of a planarization tool 210 for performing IAP, in accordance with some embodiments. FIG. 2B is a plan view showing some additional aspects of the planarization tool. It is noted that not all components are illustrated in both figures.

Referring to both figures, the planarization tool 210 includes a housing 212 that contains a chamber 214 for providing a sealed environment for the various components. One or more load ports (not shown) can be coupled to the wall of the chamber 214 to permit wafer substrates to enter and exit the tool 210 using a robotic wafer transfer system (not illustrated). A door 216 is illustrated which permits access to the chamber 214. The tool 210 includes a transport system 220 for moving the substrate 110 relative to the superstrate 200. As illustrated here, the transport system is in the form of a movable stage 222 which can move in at least the X-axis and the Y-axis relative to the superstrate 200. The transport system 220 includes an upper surface 224 upon which the substrate 110 is located to face the superstrate. The upper surface has a surface area sufficient for holding the substrate. The substrate can be fixed in place upon the transport system, for example, using a vacuum, or an electrostatic force, or a physical lip/groove that surrounds the sides of the substrate. In particular embodiments, the upper surface is sized for a substrate having a diameter of at least 150 millimeters, such as a 200-mm or a 300-mm wafer.

A deposition system 230 is present for depositing the curable material upon the substrate. As illustrated here, the deposition system 230 includes a printhead 232 like that used in inkjet printing. Very generally, the printhead includes an array of jets or nozzles arranged in one or more rows. Each nozzle is connected to an individual chamber. By selectively activating the nozzles to eject drops as the wafer substrate and/or printhead are moved relative to one another, the deposited drops can form a pattern determined by the topography of the top layer of the wafer substrate to optimize the flatness of the top layer of the wafer substrate. In FIG. 2B, the printhead 232 is illustrated as having a length 234 that is about equal to the diameter 115 of the wafer substrate 110, but this is not required. In some embodiments, the length 234 of the printhead is about equal to the length 202 of the field-sized superstrate 200.

In a piezoelectric printhead, each chamber typically includes a flexible diaphragm and a piezoelectric transducer attached to the diaphragm. When a voltage is applied to the piezoelectric transducer, the piezoelectric transducer deforms, causing the diaphragm to flex and a quantity of curable material in the individual chamber to be expelled through the nozzle. The flexing can also be used to draw replacement curable material into the individual chamber from a main reservoir 236.

In an electrostatic printhead, each chamber typically includes a flexible diaphragm and a conductor spaced on the opposite side of the flexible diaphragm, creating an actuator chamber therebetween. When a voltage is applied between the diaphragm and the conductor, the diaphragm flexes toward the conductor, which draws curable material from the main reservoir into the individual chamber. When the voltage signal is removed, the restoring force of the diaphragm membrane causes the curable material in the individual chamber to be expelled through the nozzle.

The curable material itself may be any suitable material, such as a polymerizable material. Such polymerizable materials may include, for example, acrylate and epoxy monomers or resins. The resulting polymer may be electrically insulating or electrically conductive, as desired. It is noted the resulting polymer is different from photoresist, and is not intended to be removable after curing. The curable material should also be viscous in its uncured state, or in other words it does not flow easily.

The superstrate 200 is also part of the planarization tool. The superstrate itself generally has a uniform thickness 206. In particular embodiments, the superstrate is made of a glass, such as phosphosilicate, fluorosilicate, borosilicate, or silica. The underside of the superstrate is flat. For purposes of the present disclosure, the term “flat” or “planar”, when used in reference to a surface of a layer, refers to the surface area within the field having a maximum surface roughness of 3 nanometers between the lowest point of the field and the highest point of the field.

Continuing, the field-sized superstrate 200 may be attached to a frame 208. For example, the frame permits the superstrate to be moved in the Z-axis towards and away from the transport system 220 and the wafer substrate 110. The superstrate may also be rotated along other axes (e.g. roll, yaw, pitch) to obtain a planar or flat surface upon the top layer of the substrate. In FIG. 2B, the width 204 and length 202 of the superstrate 200 are indicated. In some embodiments, the superstrate has a width of about 20 mm to about 60 mm, and has a length of about 30 mm to about 100 mm. Other dimensional endpoints and ranges are also within the scope of this disclosure.

The planarization tool 210 also includes a radiation source 240, which is used to cure the curable material. In particular embodiments, the radiation source emits UV radiation. In more particular embodiments, the emitted radiation has a wavelength of about 300 nanometers to about 400 nanometers.

In particular embodiments, the emitted radiation passes through the superstrate, as indicated by arrow 242 as it travels towards the substrate 110. In such embodiments, the superstrate should be transparent to UV radiation. For example, desirably, the superstrate has a transmittance (T%), when measured at the wavelength emitted by the radiation source, of greater than 90%, or of greater than 95%, or of greater than 96%, or of greater than 97%.

In some embodiments, it may be desirable to be able to perform annealing of the wafer substrate. Thus, a heat source 250 may be present within the housing of the planarization tool. The heat source may be configured to generate a temperature of, for example, from about 40° C. to about 1100° C., or other appropriate range. It should be noted this is the temperature generated within the housing, and is not the temperature that must be reached by the wafer substrate. In some embodiments, it might also be desirable to control the pressure within the chamber and perform the methods at low pressure (for example, below 0.01 MPa). Thus, a vacuum pump 252 might be present.

An imaging system 254 may also be present in the planarization tool. The imaging system may be used, for example, to monitor the substrate 110, the superstrate 200, the deposition system 230, and/or the curable material during deposition and the curing process. The imaging system may include one or more cameras, as well as any other optical components needed for imaging (e.g. lenses, prisms, mirrors, etc.) or other sensors. The imaging system can operate at any applicable useful wavelength(s).

A topography measurement system 256 may also be part of the planarization tool, located within the housing 212. Alternatively, the topography measurement system may be a separate tool. The topography of the top layer of the wafer substrate can be measured, for example, using atomic force microscopy, ellipsometry, or an optical surface profiler. Such tools are desirably accurate to within 1 nanometer.

A controller 258 may be used to control the various components of the planarization tool, and to measure various conditions within the chamber for the planarization process. The system may also include sensors (not shown) for monitoring applicable parameters. For example, such sensors may include those for tracking the location of the various components, the deposition rate of the curable material, the down force of the superstrate, the speed of the transport system, the temperature of the chamber, etc. The controller can also determine whether to activate or deactivate the system, how/when to move the transport system, control the motion of any automated handling system that may be present, etc. It is noted that these various parameters may not have to be held steady during operation, and could be changed by the controller operating a computer program which alters their setpoints as appropriate. The controller may also include a user interface for communicating with operators. Dashed lines are shown connecting the controller 258 to the topography measurement system 256, imaging system 254, deposition system 230, transport system 220, superstrate 200, radiation source 240, and heat source 250.

The controller may be implemented on one or more general purpose computers, special purpose computer(s), a programmed microprocessor or microcontroller and peripheral integrated circuit elements, an ASIC or other integrated circuit, a digital signal processor, a hardwired electronic or logic circuit such as a discrete element circuit, a programmable logic device such as a PLD, PLA, FPGA, Graphical card CPU (GPU), or PAL, or the like. Such devices typically include at least memory for storing a control program (e.g. RAM, ROM, EPROM) and a processor for implementing the control program.

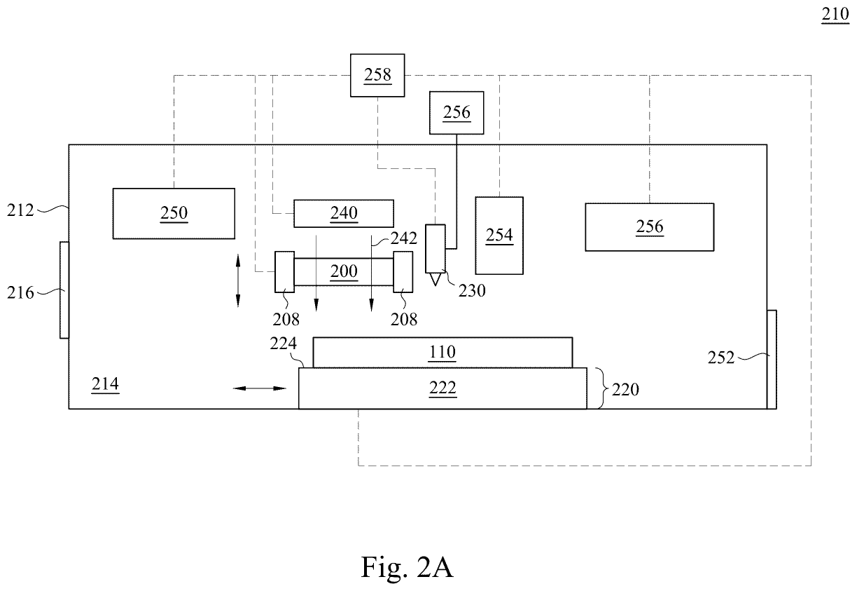

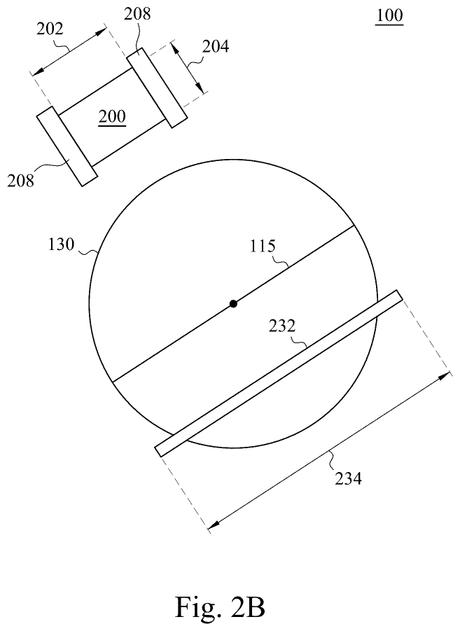

FIG. 3 is a flow chart illustrating a method 300 for planarizing a top layer of a substrate 110, in accordance with some embodiments. Some steps of the method are also illustrated in FIGS. 4-9, which are Y-axis cross-sectional views. These figures provide different views for better understanding, and the following discussion should also be broadly construed. It is noted that not all steps described in the flow chart are required, and not all method steps are described in the flow chart.

Referring first to FIG. 4, the substrate 110 has a front side 112 and a back side 114. The substrate is a wafer made of a semiconducting material in certain embodiments. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Here, the wafer substrate 110 is also illustrated with a material layer 120 formed of a different material, such as a dielectric material or an electrically conductive material, upon the front side 112 which serves as the top layer. The top layer has a topography that includes valleys 122 and peaks 124. Generally, a valley lies between two peaks. However, it is noted the peaks may have different heights.

Initially, in step 305 of FIG. 3 and referring to the magnified view of FIG. 4, the topography of one or more fields on the top layer 140 of the substrate 110 is measured. This may be done using the topography measurement system previously described, for as much surface area of the substrate as desired. Generally, the topography is measured for at least a surface area corresponding to the field-sized superstrate. In other embodiments, the topography of the entire wafer substrate can be measured in this operation. In FIG. 4, three different fields 130, 132, 134 are indicated. Again, a field may correspond to one or more shots as illustrated in FIGS. 1A-1C.

Next, in step 310 of FIG. 3, a deposition pattern for obtaining a flat surface is determined. This is done using the data obtained by the topography measurement system and known methods and parameters. For example, the controller 258 may make these calculations. Generally, at least the valleys are filled with the curable material. If desired, additional curable material is also deposited such that the resulting cured material/layer will cover the entirety of the top layer 140 within the field.

Then, in step 315 of FIG. 3 and referring to FIG. 4, a curable material 150 is deposited (in the form of droplets) upon the field 130 according to the measured topography and/or the determined deposition pattern. This is done via the deposition system 230, for example by ink jetting as described above. In some embodiments, the substrate 110 may be moved relative to the deposition system using the transport system (not shown here) to complete the deposition of curable material over the field. In other embodiments, the deposition system itself is large enough to deposit curable material upon the entire surface area of the field. Generally, the resulting deposited curable material will not be uniform over the surface area of the field.

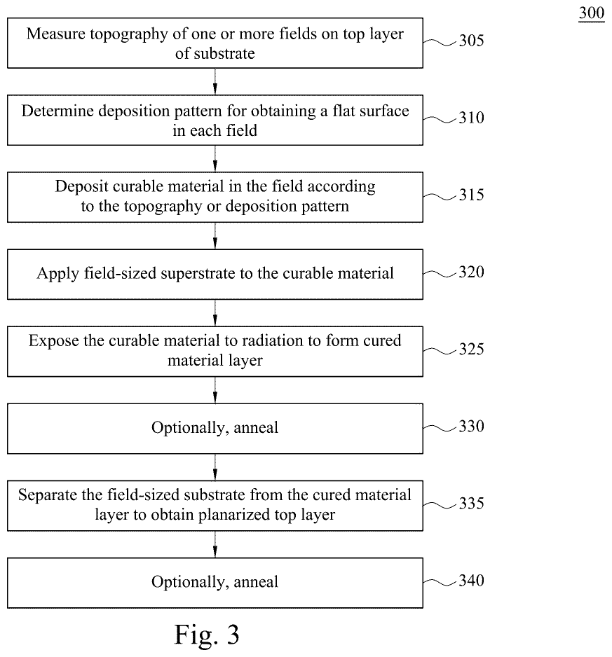

Then, in step 320 of FIG. 3 and referring to FIG. 5, the field-sized superstrate 200 is applied to the curable material 150. The superstrate 200 may be described as imprinting the curable material. This may be done, for example, by lowering the superstrate 200 down to contact the curable material or by raising the wafer substrate up to contact the superstrate. As a result, the curable material spreads out and forms a flat surface 152 underneath the superstrate. As illustrated here, the curable material may also be described as forming a new top layer 140 upon the substrate. The volume between the material layer 120 and the superstrate 200 is desirably completely filled by the curable material and does not contain bubbles or voids.

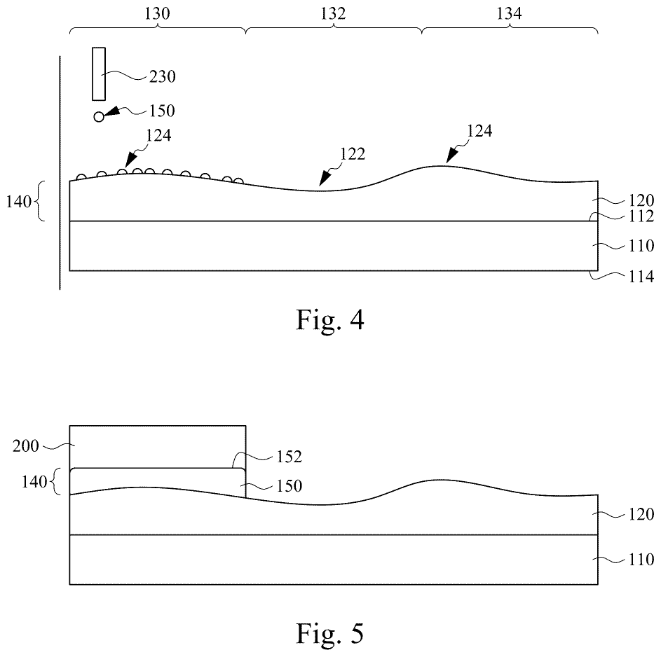

FIG. 6 is a further magnified view. As seen here, when the superstrate 200 presses down on the viscous curable material, some of the curable material may be pushed sideways and out from under the superstrate, and form a hump or recess 154 on the edges of the superstrate 200. The presence of these humps/recesses may be acceptable in the methods of the present disclosure, and can be accounted for in subsequent processing.

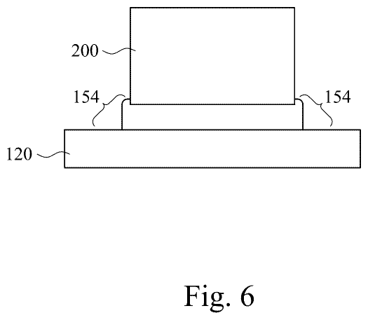

Continuing, in step 325 of FIG. 3 and referring to FIG. 7, the curable material is exposed to radiation from the radiation source 240, resulting in a cured material layer 160. For example, the curable material is polymerized due to the radiation exposure. In particular embodiments, the radiation passes through the field-sized superstrate 200. However, this is not required. In additional particular embodiments, the radiation is directed such that only the curable material under the superstrate is cured, and for example the hump/recess 154 of FIG. 6 is not cured. This may permit the curable material in the hump/recess to be further molded.

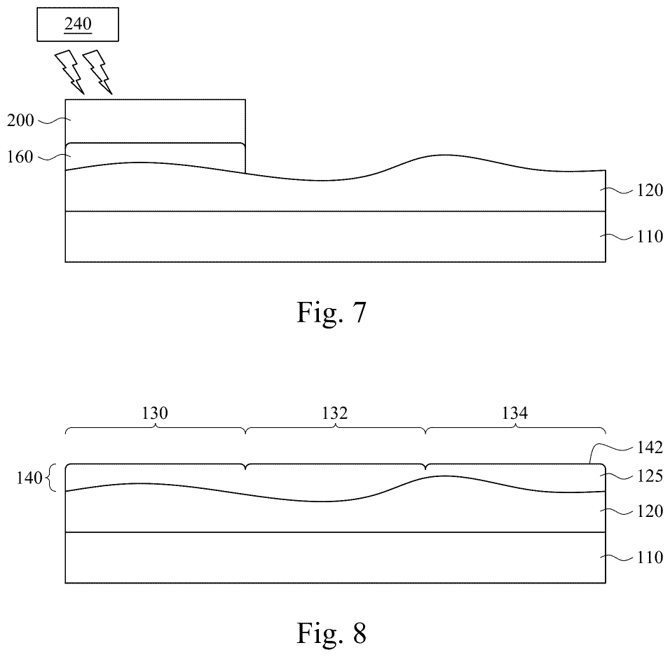

Then, in step 335 of FIG. 3 and referring to FIG. 8, the field-sized superstrate is lifted off the cured material to obtain the planarized top layer 140. Put another way, the superstrate is separated from the cured material layer. For example, this may be done by moving the superstrate upwards. It is contemplated that the superstrate may be gradually removed from the planarized top layer. For example, one edge of the superstrate may be lifted off first, and the remainder of the superstrate gradually separated. This may aid, for example, in reducing liftoff force applied to the cured layer, which may also aid in reducing surface variations. The resulting upper surface 142 of the top layer 140 is flatter than the upper surface 125 of the material layer 120.

In some embodiments, annealing may be performed after the curing step 325. Such annealing may be performed as step 330 before separating the field-sized superstrate, or as step 340 after separating the field-sized superstrate. As a result, a planarized top layer 140 is formed or obtained.

These method steps may be repeated over the wafer substrate. FIG. 8 illustrates the wafer substrate 110 after all three fields 130, 132, 134 have been planarized. In this illustration, recesses 154 are visible between the fields.

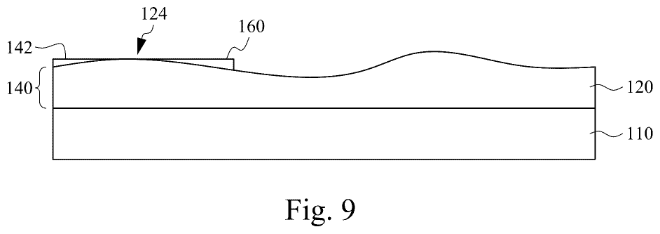

FIG. 9 is an alternative embodiment. Here, the curable material is only applied to fill the valleys of the material layer 120. As a result, when the superstrate is applied to form a flat surface, the peaks 124 of the material layer are exposed upon the resulting upper surface 142 of the top layer 140 after curing is performed. The curable material layer 160 is also illustrated here.

It is noted that the methods of the present disclosure are applicable to any layer built upon the substrate which together make up an integrated circuit Integrated circuits are built up from different patterns of electrically conductive materials and electrically insulating materials to make useful components. Suitable examples of integrated circuit components may include, for example and without limitation, active components (e.g., transistors), passive components (e.g., capacitors, inductors, resistors, and the like), or combinations thereof. These components may be made from electrically conductive materials such as metals like copper, aluminum, gold, tungsten, iron, ruthenium, iridium, and alloys thereof. Suitable examples of electrically insulating materials (i.e. dielectric materials) may include oxides such as silicon dioxide (SiO₂), aluminum oxide (Al₂O₃), tantalum oxide (Ta₂O₅), zirconium dioxide (ZrO₂), or hafnium dioxide (HfO₂); nitrides such as silicon carbon nitride (SiCN), silicon nitride (SiN), hafnium oxynitride (HfOₓN_{y}), zirconium oxynitride (ZrOₓN_{y}), or silicon oxynitride (SiOₓN_{y}), where 0<x, y, ≤1; silicates like hafnium silicates (HfSiₓO_{y}) or zirconium silicates (ZrSiₓO_{y}), where 0<x, y, ≤1; polysilicon, phosphosilicate glass (PSG), fluorosilicate glass (FSG), undoped silicate glass (USG), high-stress undoped silicate glass (HSUSG), borosilicate glass (BSG), a high-k dielectric material, or a low-k dielectric material.

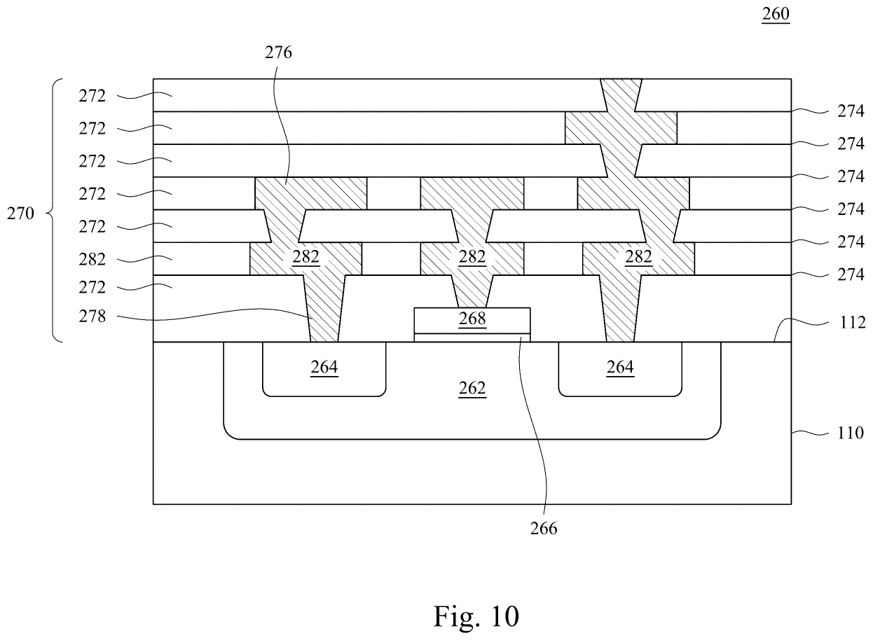

For example, FIG. 10 is a cross-sectional view of a semiconductor die 260 that includes a planar transistor. A well 262 of a first dopant type is formed within the substrate 110. Source/drain (S/D) electrodes 264 are present on opposite sides of the well. A gate dielectric layer 266 is shown on the front side 112 of the substrate and over the well 262. A gate electrode 268 is located on and contacts the gate dielectric layer 266. A redistribution layer (RDL) 270 is present on the front side 112 of the substrate over the S/D electrodes 264 and the gate electrode 268. As illustrated here, the RDL is formed from a plurality of dielectric sublayers 272 and a plurality of etch stop sublayers 274. Metal interconnects 276 and metal vias 278 are present through the RDL, and contact the three electrodes 264, 268.

The methods of the present disclosure can be used to planarize each of the substrate 110, the gate electrode 268, and each dielectric sublayer 272 or etch stop sublayer 274 using an appropriate selection for the curable material as desired. For example, the metal interconnects 280 in dielectric sublayer 282 are typically formed by first forming the dielectric sublayer, then etching through the sublayer using an etch process whose depth is controlled, in part, by the duration of the etching step. Having a flat surface improves the uniformity between the three interconnects illustrated here, which also improves overall device yield.

The methods, systems/tools, and resulting semiconducting devices have several advantages. Compared to a large wafer-sized superstrate, quality control is easier for producing and confirming that a smaller device, i.e. the field-sized superstrate, has a completely flat surface which can then be transferred to the curable material. It is believed that a topography variation smaller than 2 nm can be obtained within the field using the field-sized superstrate. In addition, process parameters for each field can be fine-tuned to improve planarization results. The planarization-by-field process avoids the need to planarize the edges of the wafer substrate where partial dies might be formed, which can reduce operating costs. Loading effects that might result from pattern density and pad size can be reduced when compared to other planarization techniques such as chemical-mechanical planarization (CMP) or spin coating. The improved planarity also results in improved uniformity and reduced variation in the resulting structures formed after process steps such as deposition and etching. This can improve critical dimension (CD) and reduce mechanical stresses within the field that might otherwise occur.

The present disclosure thus relates in some embodiments to various methods for planarizing a layer of a semiconducting wafer substrate. The topography of a field on the layer is measured. A curable material is deposited upon or within the field according to the measured topography. A field-sized superstrate is applied to the curable material to create a flat surface. The curable material is cured. The field-sized superstrate is separated from the cured material to obtain the planarized layer.

Also disclosed herein are planarization tools for planarizing a semiconducting wafer substrate, comprising: a field-sized superstrate; a transport system, a deposition system, and a radiation source. The transport system moves an associated substrate relative to the field-sized superstrate. The deposition system is used to deposit an associated curable material upon the associated substrate. The radiation source can apply radiation through the field-sized superstrate. The tools may further include a heat source for annealing, an imaging system, and/or a topography measurement system.

Also disclosed herein are additional methods for planarizing a top layer of a semiconducting wafer substrate. The topography of a field on the top layer is measured. The field has a surface area of at most ⅓ a surface area of the substrate. A deposition pattern for obtaining a flat surface is determined. The substrate is moved relative to a deposition system using a transport system to deposit a curable material upon the field according to the determined deposition pattern. The curable material is imprinted with a field-sized superstrate to create a planar surface. The curable material is cured, such as by using a radiation source. The field-sized superstrate is lifted off the cured material to obtain the planarized top layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for planarizing a layer of a semiconducting wafer substrate, comprising:
measuring a topography of a field on the layer;
depositing a curable material upon the field according to the measured topography;
applying a field-sized superstrate to the curable material to create a flat surface;
curing the curable material; and
separating the field-sized superstrate from the cured material to obtain the planarized layer.

2. The method of claim 1, further comprising annealing after curing the curable material.

3. The method of claim 1, wherein the curable material is deposited by ink jetting.

4. The method of claim 1, wherein the field-sized superstrate has an area of about 800 mm² to about 900 mm².

5. The method of claim 1, wherein the field-sized superstrate has an area of about 1600 mm² to about 6000 mm².

6. The method of claim 1, wherein the field-sized superstrate has a width of about 20 mm to about 60 mm, and has a length of about 30 mm to about 100 mm.

7. The method of claim 1, wherein the curing is performed using radiation that has a wavelength of about 300 nanometers to about 400 nanometers.

8. The method of claim 1, wherein the curable material is a polymerizable material.

9. The method of claim 1, wherein the topography is measured using atomic force microscopy (AFM), ellipsometry, or an optical surface profiler.

10. A planarization tool for planarizing an associated semiconducting wafer substrate, comprising:
a field-sized superstrate;
a transport system for moving the associated substrate relative to the field-sized superstrate;
a deposition system for depositing an associated curable material; and
a radiation source for curing the associated curable material.

11. The tool of claim 10, further comprising a heat source for annealing.

12. The tool of claim 10, further comprising an imaging system.

13. The tool of claim 10, further comprising a topography measurement system.

14. The tool of claim 10, wherein the transport system is sized for a semiconducting wafer substrate having a diameter of at least 150 mm.

15. The tool of claim 10, wherein the field-sized superstrate has an area of about 800 mm² to about 6000 mm².

16. The tool of claim 10, wherein the field-sized superstrate has a width of about 20 mm to about 60 mm, and has a length of about 30 mm to about 100 mm.

17. The tool of claim 10, wherein the radiation source emits radiation having a wavelength of about 300 nanometers to about 400 nanometers.

18. The tool of claim 10, wherein the field-sized superstrate is transparent to a wavelength emitted by the radiation source.

19. A method for planarizing a top layer of a semiconducting wafer substrate, comprising:
measuring a topography of a field on the top layer, wherein the field has a surface area of at most ⅓ a surface area of the substrate;
determining a deposition pattern for obtaining a planar surface;
moving the substrate relative to a deposition system using a transport system to deposit a curable material upon the field according to the determined deposition pattern;
imprinting the curable material with a field-sized superstrate to create a flat surface;
curing the curable material; and
lifting the field-sized superstrate off the cured material to obtain the planarized top layer.

20. The method of claim 18, wherein the curable material is cured by radiation that passes through the field-sized superstrate.
